(19) United States
(12) Patent Application Publication
(10) Pub. No.: US 2024/0071848 A1
(43) Pub. Date: Feb. 29, 2024

(54) THROUGH GLASS VIAS (TGVS) IN GLASS CORE SUBSTRATES

(71) Applicant: Intel Corporation, Santa Clara, CA (US)

(72) Inventors: Bohan SHAN, Chandler, AZ (US); Haobo CHEN, Gilbert, AZ (US); Brandon C. MARIN, Gilbert, AZ (US); Srinivas V. PIETAMBARAM, Chandler, AZ (US); Bai NIE, Chandler, AZ (US); Gang DUAN, Chandler, AZ (US); Kyle ARRINGTON, Gilbert, AZ (US); Ziyin LIN, Chandler, AZ (US); Hongxia FENG, Chandler, AZ (US); Yiqun BAI, Chandler, AZ (US); Xiaoying GUO, Chandler, AZ (US); Dingying David XU, Chandler, AZ (US); Jeremy D. ECTON, Gilbert, AZ (US); Kristof DARMAWIKARTA, Chandler, AZ (US); Suddhasattwa NAD, Chandler, AZ (US)

(21) Appl. No.: 17/895,916

(22) Filed: Aug. 25, 2022

(51) Int. Cl. H01L 23/15; H01L 21/48; H01L 23/498

(52) U.S. Cl. CPC H01L 23/15; H01L 21/486; H01L 23/49816; H01L 23/49827

(57) ABSTRACT

Embodiments disclosed herein include package substrates. In an embodiment, the package substrate comprises a core, where the core comprises glass. In an embodiment, a first layer is under the core, a second layer is over the core, and a via is through the core, the first layer, and the second layer. In an embodiment a width of the via through the core is equal to a width of the via through the first layer and the second layer. In an embodiment, the package substrate further comprises a first pad under the via, and a second pad over the via.

### TECHNICAL FIELD

Embodiments of the present disclosure relate to electronic packages, and more particularly to glass cores with through glass vias (TGVs).

### BACKGROUND

Advanced packaging applications are moving towards the inclusion of glass cores instead of organic cores. Glass cores may comprise a substrate that is essentially all glass, as opposed to an organic core that may have reinforcement that includes glass fibers or the like. In order to deposit copper (e.g., for vias, pads, etc.) on a glass core, a buffer layer may be needed. The buffer layer permits the copper deposition and may also function as a stress mitigation feature.

However, the buffer layer requires an additional via extension. The via extension is a portion of the via that extends through the buffer layer. In existing architectures the via extension is narrower than the through glass via (TGV) that passes through the glass core. Due to the narrower geometry, the current is pinched and the maximum current that can pass through the TGV is limited. This negatively impacts the power density and is a significant drawback when using glass cores.

### BRIEF DESCRIPTION OF THE DRAWINGS

FIG. 1 is a cross-sectional illustration of a glass core that includes a narrow via extension through a buffer layer, in accordance with an embodiment.

FIG. 2 is a cross-sectional illustration of a glass core with buffer layers and a via that passes through the glass core and the buffer layers, in accordance with an embodiment.

FIGS. 3A-3F are cross-sectional illustrations depicting a process for forming a package substrate with a glass core and buffer layers, where the via passes through the glass core and the buffer layers, in accordance with an embodiment.

FIG. 4A is a cross-sectional illustration of a glass core with buffer layers, where the via narrows through the buffer layers, in accordance with an embodiment.

FIG. 4B is a cross-sectional illustration of a glass core with buffer layers, where the via width expands through the buffer layers, in accordance with an embodiment.

FIG. 4C is a cross-sectional illustration of a glass core with buffer layers and an adhesion promoting layer, in accordance with an embodiment.

FIG. 4D is a cross-sectional illustration of a glass core with buffer layers and a via that has an hourglass shaped cross-section, in accordance with an embodiment.

FIGS. 5A-5H are cross-sectional illustrations depicting a process for forming a package substrate with a glass core and buffer layers, in accordance with an embodiment.

FIG. 6A is a cross-sectional illustration of a glass core with buffer layers and a via through the glass core and buffer layers that has a uniform width, in accordance with an embodiment.

FIG. 6B is a cross-sectional illustration of a glass core with buffer layers and a via through the glass core and buffer layers, with the via having an hourglass shaped cross-section through the glass core and a rectangular shaped cross-section through the buffer layers, in accordance with an embodiment.

FIGS. 7A-7F are cross-sectional illustrations depicting a process for forming a glass core with through glass vias, in accordance with an embodiment.

FIG. 8A is a cross-sectional illustration of a glass core with a via that includes a liner, in accordance with an embodiment.

FIG. 8B is a cross-sectional illustration of a glass core with a via that includes a liner with non-vertical sidewalls, in accordance with an embodiment.

FIGS. 9A-9F are cross-sectional illustrations depicting a process for forming a glass core with vias that include a liner, in accordance with an embodiment.

FIG. 10 is a cross-sectional illustration of an electronic system with a package substrate that includes a glass core with through glass vias, in accordance with an embodiment.

FIG. 11 is a schematic of a computing device built in accordance with an embodiment.

### EMBODIMENTS OF THE PRESENT DISCLOSURE

Described herein are glass cores with through glass vias (TGVs), in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

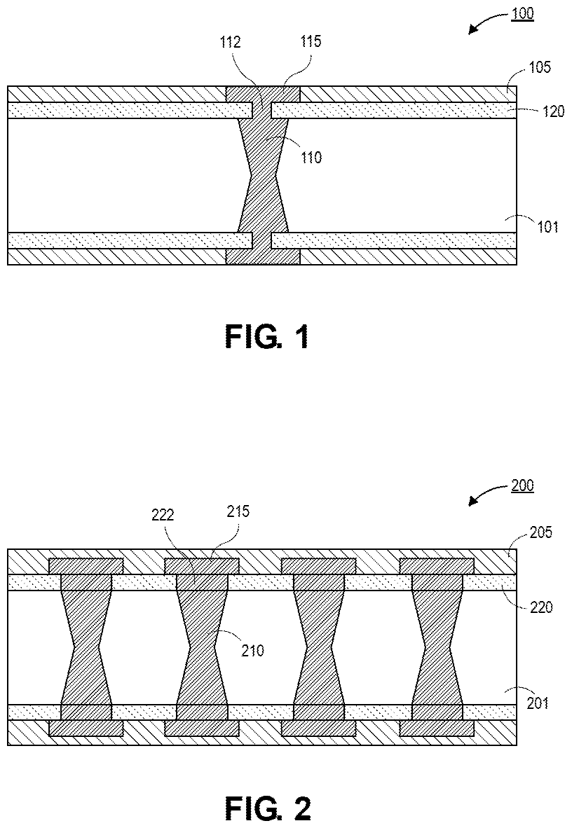

As noted above, existing glass core architectures result in vias that have a pinch point through the buffer layers. Accordingly, the power density of the glass core is limited by the reduced via width provided through buffer layers that are needed for the glass core architecture. An example of such a limited solution is shown in FIG. 1. In FIG. 1, a cross-sectional illustration of a package substrate 100 is shown. The package substrate 100 may include a core 101 that comprises glass. For example, the core 101 may be substantially all glass material. That is, a core 101 comprising glass may be different than an organic substrate that may include glass reinforcement (e.g., glass fibers). The core 101 may be any suitable thickness. For example, the core 101 may have a thickness between approximately 50 μm and approximately 1,000 μm. As used herein, “approximately” may refer to a range that is plus or minus ten percent of the stated value. For example, approximately 1,000 μm may refer to a range between 900 μm and 1,100 μm.

In an embodiment, the core 101 may include a through glass via (TGV) 110. The TGV 110 may be formed with any suitable patterning and deposition process. In some embodiments, the TGV 110 may be laser drilled or laser patterned. A laser patterned TGV 110 may use a laser to change a microstructure or phase of the glass. The exposed region is more susceptible to etching than the unexposed regions. The use of a laser based process may result in the TGV 110 having an hourglass shaped cross-section. An hourglass shaped cross-section may include a shape that narrows towards a middle, with larger ends at the top and bottom. That is, the hourglass shaped cross-section may have ends that are wider than a middle of the shape.

In an embodiment, a buffer layer 120 may be provided above and below the core 101. The buffer layer 120 may be a material that improves performance of the package substrate 100 or otherwise enables the deposition of the conductive materials. For example, the buffer layer 120 may be an adhesion promoting layer, a stress reduction layer, or the like. In an embodiment, a via 112 is provided through the buffer layer 120 in order to couple the TGV 110 to an overlying or underlying pad 115. The pads 115 may be provided in a buildup layer 105 or the like. As illustrated, the via 112 is narrower than the width of the TGV 110. As such, the maximum amount of current that can pass through the structure is limited by the via 112. This minimizes the power density for glass core 110 architectures.

Accordingly, embodiments disclosed herein include via architectures that enable wider vias through the buffer layers. The wider vias through the buffer layer may be substantially the same width as the TGV. In cases where the TGV has an hourglass shaped or otherwise tapered cross-section, the portion of the via through the buffer layer may be a width that is substantially equal to a maximum width of the TGV. The TGV and the vias through the buffer layer may be formed with a single patterning process. As such, the vias in the buffer layer may be aligned with the TGVs. For example, a centerline of the vias through the buffer layer may be substantially aligned with a centerline of the TGV. As will be appreciated, many different architectures and process flows may be used in order to improve the electrical performance of package substrates with glass cores.

Referring now to FIG. 2, a cross-sectional illustration of a package substrate 200 is shown, in accordance with an embodiment. In an embodiment, the package substrate 200 may comprise a core 201 that comprises glass. As used herein, a core that comprises glass may refer to a core that is substantially all glass. That is, a core that comprises glass is different than an organic core that includes glass reinforcement fibers or the like. In an embodiment, the core 201 may include a thickness that is between approximately 50 μm and approximately 1,000 μm. Though, it is to be appreciated that thinner or thicker cores 201 may also be used. In an embodiment, the core 201 may comprise a glass material that is suitable for laser assisted patterning processes. For example, laser exposure of the glass may result in the change of a microstructure or phase of the glass. The modified glass is then more susceptible to an etching chemistry (e.g., a wet etching chemistry) than the unmodified regions of the glass. In embodiments that utilize such a patterning process, the cross-section of the vias (e.g., TGVs) may have tapered sidewalls. In embodiments where a dual sided laser exposure is used, the cross-section of the vias (e.g., TGVs) may be hourglass shaped. For example, the TGVs 210 in FIG. 2 have the characteristic hourglass shaped cross-section.

In an embodiment, a buffer layer 220 may be provided above and below the core 201. The buffer layer 220 may include any suitable material for buffer layers 220. For example, the buffer layer 220 may be a dielectric material. The buffer layer 220 may comprise a material suitable for improving adhesion between layers in some embodiments. In a particular embodiment, the buffer layer 220 may comprise silicon and nitrogen (e.g., silicon nitride), or titanium and nitrogen (e.g., titanium nitride). Though, it is to be appreciated that other materials or material classes may also be used for the buffer layer 220.

In an embodiment, vias 222 may be provided through the buffer layer 220. The vias 222 may be aligned with the TGVs 210. That is, a centerline of the vias 222 may be substantially aligned with a centerline of the TGVs 210. As used herein, “substantially aligned” may refer to two lines that are within 5 μm of being perfectly aligned, or within 1 μm of being perfectly aligned. In an embodiment, the vias 222 may also have a width that is substantially equal to a maximum width of the TGVs 210. As used herein “substantially equal” may refer to two values that have a difference in the dimension of interest that is within ten percent of each other. For example, a width of 50 μm may be substantially equal to a width between 45 μm and 55 μm. As illustrated in FIG. 2, the edge of the vias 222 are aligned with the edge of the TGVs 210. Though, it is to be appreciated that there may be some misalignment in some embodiments, due to process variations.

In an embodiment, the vias 222 provide an electrical connection between the TGVs 210 and the overlying or underlying pads 215. The pads 215 may be provided in a buildup layer 205. The buildup layer 205 may be an organic buildup film or other similar material. Typically, the buildup layer 205 is applied to the structure using a lamination process or the like. In an embodiment, the pads 215 may have a width that is wider than the width of the vias 222 and the width of the TGVs 210. The pads 215 may then be coupled to additional conductive routing within the package substrate 200 (e.g., in layers above or below the pads 215). These additional layers are omitted from FIG. 2 in order to not obscure embodiments of the disclosure described herein.

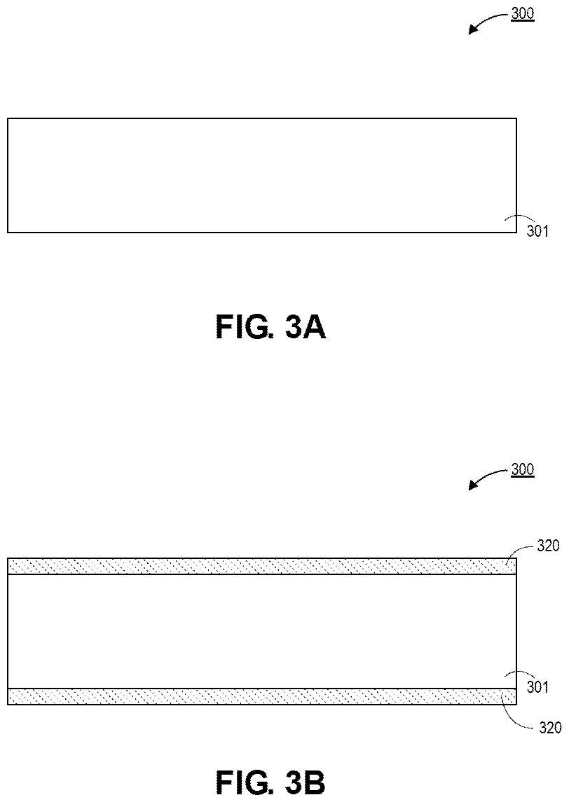

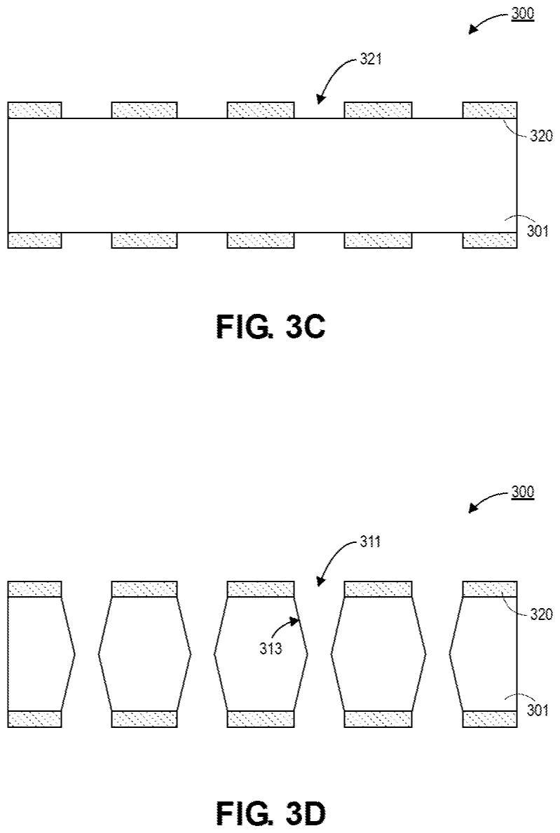

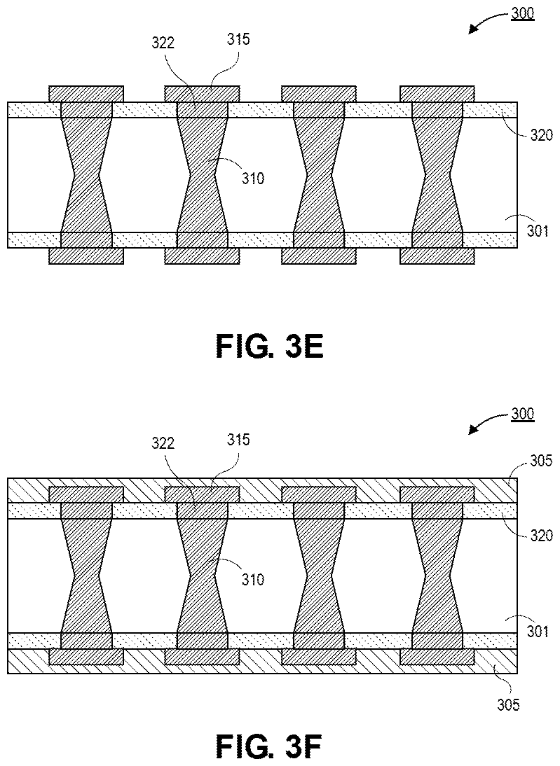

Referring now to FIGS. 3A-3F, a series of cross-sectional illustrations depicting a process for forming a package substrate 300 is shown, in accordance with an embodiment. In an embodiment, the package substrate 300 may be substantially similar to the package substrate 200 shown in FIG. 2. The package substrate 300 may include a glass core with buffer layers above and below the glass core. In an embodiment, a TGV may be coupled to vias through the buffer layers. The vias through the buffer layer may have a width that is equal to a maximum width of the TGV.

Referring now to FIG. 3A, a cross-sectional illustration of a package substrate 300 at a stage of manufacture is shown, in accordance with an embodiment. In an embodiment, the package substrate 300 may comprise a core 301 that comprises glass. In an embodiment, the core 301 may be a glass material that is suitable for laser assisted patterning operations. For example, laser exposure of the core 301 may result in a change to the microstructure or phase of the core 301 that renders the exposed region more susceptible to an etching process (e.g., a wet etching chemistry). In an embodiment, the core 301 may have any suitable thickness. In a particular embodiment, the thickness of the core 301 may be between approximately 50 μm and approximately 1,000 μm. Though, thinner or thicker cores 301 may also be used in some embodiments.

Referring now to FIG. 3B, a cross-sectional illustration of the package substrate 300 after buffer layers 320 are provided above and below the core 301 is shown, in accordance with an embodiment. The buffer layers 320 may be a material that provides improved adhesion for subsequent processing layers. The buffer layers 320 may also provide improved mechanical robustness for the package substrate. In a particular embodiment, the buffer layers 320 may comprise silicon and nitrogen (e.g., silicon nitride), or titanium and nitrogen (e.g., titanium nitride). Though, other materials or material classes may also be used in some embodiments. For example, the buffer layers 320 may comprise a photoimageable dielectric (PID). In an embodiment, the buffer layers 320 may have a thickness that is between approximately 5 μm and approximately 20 μm. However, thinner or thicker buffer layers 320 may also be used in some embodiments.

Referring now to FIG. 3C, a cross-sectional illustration of the package substrate 300 after openings 321 are formed in the buffer layers 320 is shown, in accordance with an embodiment. In an embodiment, the buffer layers 321 may be patterned with patterning and etching process. For example, a photoresist mask may be applied over the buffer layers 320, and the photoresist mask may be exposed and patterned. The pattern in the photoresist mask may then be transferred into the buffer layers 320 using an etching process, such as a dry etching process or the like. In instances where the buffer layers 320 are PID materials, the buffer layers 320 may be directly exposed and patterned without an overlying photoresist layer.

Referring now to FIG. 3D, a cross-sectional illustration of the package substrate 300 after via openings 311 are formed through the core 301 is shown, in accordance with an embodiment. In an embodiment, the via openings 311 may be formed with a laser assisted etching process. For example, a laser may expose the core 301 through the openings 321 in the buffer layers 320. The laser exposure may result in a change to the microstructure or phase of the core 301. The exposed regions are more susceptible to an etching chemistry than the unexposed regions of the core 301. In such an embodiment, the sidewalls 313 of the via openings 311 may be tapered. In a particular embodiment, a dual sided patterning process is used. In such an embodiment, the sidewalls 313 of the via openings 311 may have an hourglass shaped cross-section. That is the tops and bottoms of the via openings 311 may be wider than midpoints (in the Z-direction) of the via openings 311. While an hourglass shaped cross-section is shown, a trapezoidal shaped cross-section may also be used (e.g., when a single sided patterning process is used). In an embodiment, a maximum width of the via openings 311 may be substantially equal to a width of the openings 321 through the buffer layers 320. At the interface between the buffer layers 320 and the core 301, the edges of the openings 321 may be aligned with the edge of the via openings 311.

Referring now to FIG. 3E, a cross-sectional illustration of the package substrate 300 after a conductive material plating process is shown, in accordance with an embodiment. In an embodiment, the conductive material may include copper or the like. In some embodiments, an electroless plating process or an electrolytic plating process may be used to form the conductive features. The conductive features may include a TGV 310 that passes through the core 301. The TGV 310 may have an hourglass shaped cross-section in some embodiments. As shown, vias 322 may pass through the buffer layers 320. The vias 322 may electrically couple the TGVs 310 to the overlying or underlying pads 315. The vias 322 may have a rectangular cross-section with a width that is substantially equal to a maximum width of the vias 322. Accordingly, there is no reduction in the width of the vias 322 that results in a decrease in the maximum amount of current that can pass through the TGVs 310 and the vias 322. In an embodiment, the pads 315 may have a width that is greater than a width of the vias 322 through the buffer layers 320. While shown as having distinct interfaces between the various features, it is to be appreciated that the conductive material may have no seams in some embodiments.

Referring now to FIG. 3F, a cross-sectional illustration of the package substrate 300 after buildup layers 305 are applied over the core 301 is shown, in accordance with an embodiment. In an embodiment, the buildup layers 305 may be dielectric material, such as buildup film or the like. The buildup layers 305 may be formed over the buffer layers 320 using lamination processes or the like. While a single buildup layer 305 is shown above and below the core 301, it is to be appreciated that any number of buildup layers 305 may be provided above and/or below the core 301. The buildup layers 305 may comprise conductive routing (e.g., pads, traces, vias, etc.) that electrically couples the TGVs 310 to other features on the package substrate 300. The additional conductive features are omitted from FIG. 3F in order to not obscure embodiments disclosed herein.

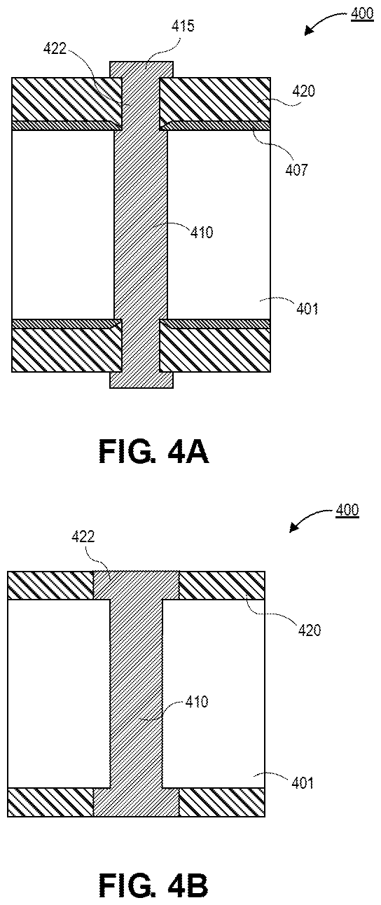

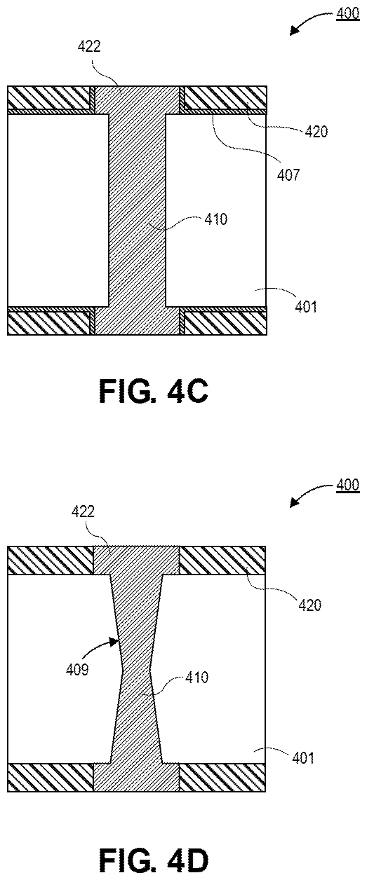

Referring now to FIG. 4A, a cross-sectional illustration of a package substrate 400 is shown, in accordance with an embodiment. As shown, the package substrate 400 comprises a core 401, such as a glass core 401. The core 401 may include a TGV 410. A buffer layer 420 may be coupled to the core 401 through an adhesion promoting layer 407. As shown, the TGV 410 is coupled to a narrower via 422 that passes through the buffer layers 420. The narrower vias 422 are choke points for current passing from the TGV 410 to the overlying and underlying pads 415 over the buffer layers 420. Accordingly, the electrical performance of the package substrate 400 in FIG. 4A is sub-optimal. Accordingly, embodiments disclosed herein include architectures with vias 422 through the buffer layers 420 that are wider than a maximum width of the TGV 410. This improves electrical performance since there is no current choke point along the electrical path through the core 401.

Referring now to FIG. 4B, a cross-sectional illustration of a package substrate 400 is shown, in accordance with an embodiment. In an embodiment, the package substrate 400 comprises a core 401. The core 401 may comprise glass in some embodiments. The core 401 may be any suitable thickness (e.g., between approximately 50 μm and approximately 1,000 μm). In an embodiment, a TGV 410 is provided through the core 401. The TGV 410 may have substantially vertical sidewalls in some embodiments. Though, as will be described in greater detail below, the sidewalls of the TGV 410 may also be tapered in some embodiments.

In an embodiment, buffer layers 420 may be provided above and below the core 401. The buffer layers 420 may comprise silicon and nitrogen (e.g., silicon nitride), or titanium and nitrogen (e.g., titanium nitride). Though it is to be appreciated that other materials or material classes may also be used for the buffer layers 420. In an embodiment, vias 422 may pass through the buffer layers 420. The vias 422 may have a width that is greater than a width of the TGV 410. As will be described in greater detail below, the vias 422 may have a centerline that is offset from a centerline of the TGV 410. This is the result of separate patterning processes being used for the TGV 410 and the vias 422.

Referring now to FIG. 4C, a cross-sectional illustration of a package substrate 400 is shown, in accordance with an additional embodiment. The package substrate 400 in FIG. 4C may be substantially similar to the package substrate 400 in FIG. 4B, with the addition of an adhesion promoting layer 407. The adhesion promoting layer 407 may be a material that improves the adhesion between the buffer layers 420 and the core 401. In an embodiment, the adhesion promoting layer 407 may be provided between the buffer layers 420 and the core 401. In an additional embodiment, the adhesion promoting layer 407 may be provided between the sidewalls of the vias 422 and the buffer layers 420. In an embodiment, the adhesion promoting layer 407 may be disposed over a top surface of the vias 422, and subsequently be removed with a planarizing process (e.g., chemical mechanical planarizing (CMP)) used to expose the vias 422.

Referring now to FIG. 4D, a cross-sectional illustration of a package substrate 400 is shown, in accordance with yet another embodiment. In an embodiment, the package substrate 400 in FIG. 4D is substantially similar to the package substrate 400 in FIG. 4B, with the exception of the shape of the TGV 410. Instead of having vertical sidewalls, the TGV 410 has tapered sidewalls 409. For example, the TGV 410 may have an hourglass shaped cross-section when a dual sided patterning process is used to form the TGV 410. As shown, a maximum width of the TGV 410 may be narrower than a width of the vias 422 through the buffer layers 420. In some embodiments, an adhesion promoting layer (not shown) that is similar to the adhesion promoting layer 407 in FIG. 4C may also be included with the tapered sidewall 409 embodiment.

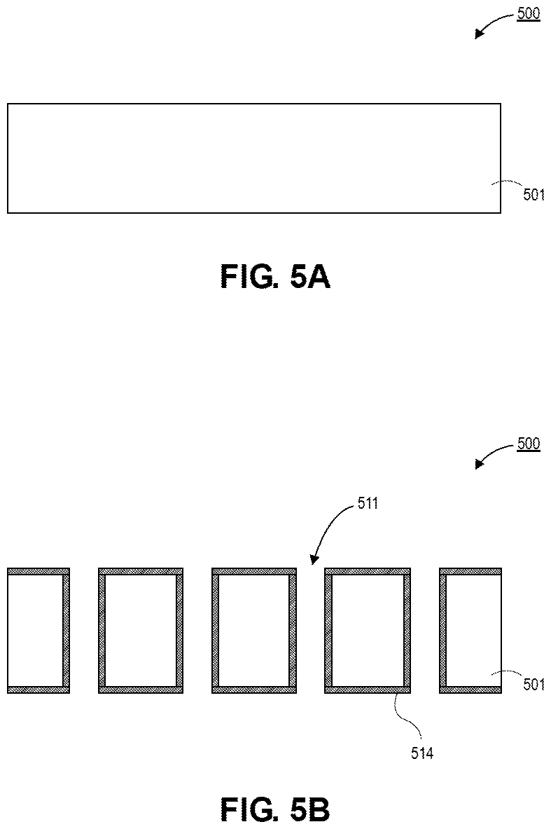

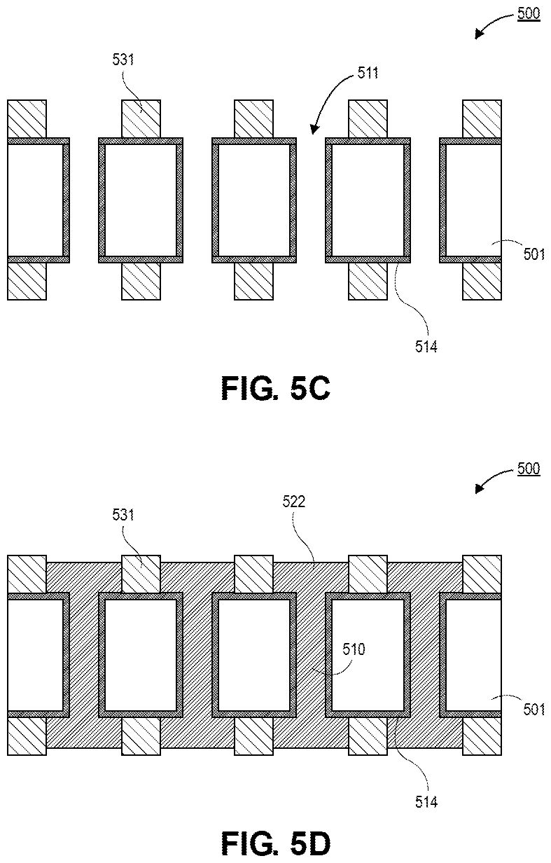

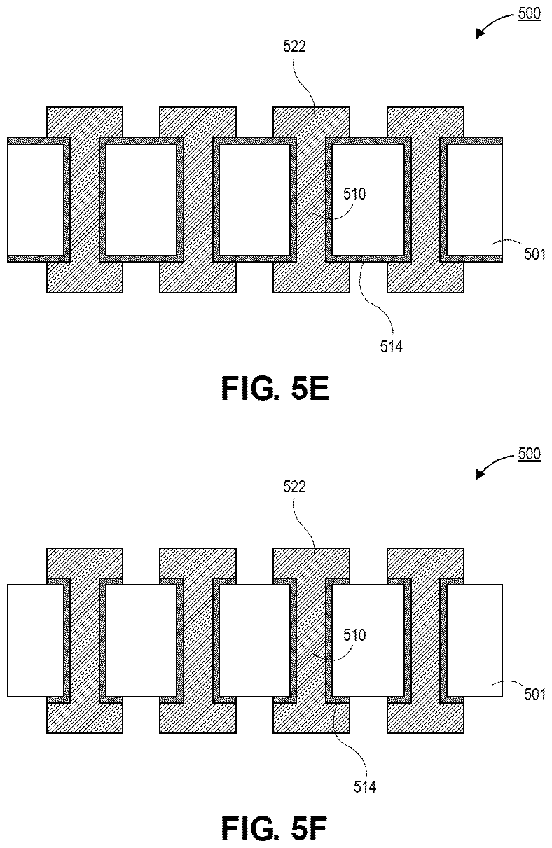

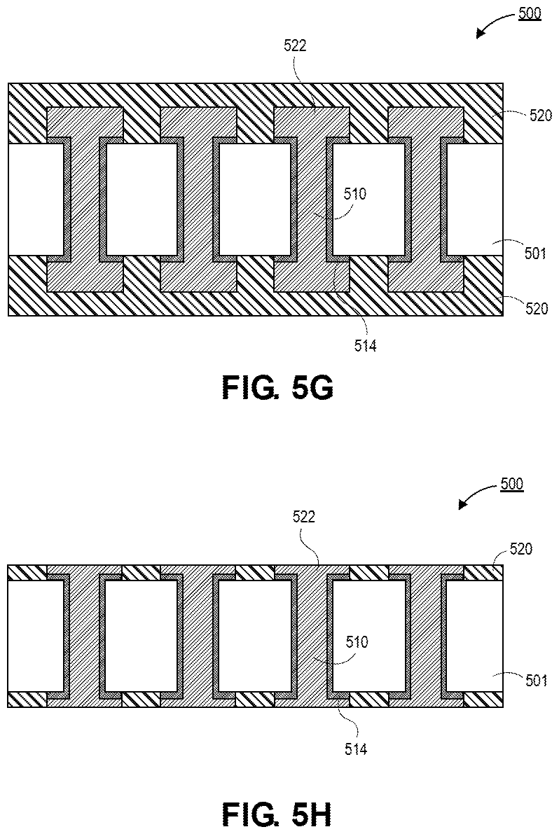

Referring now to FIGS. 5A-5H, a series of cross-sectional illustrations depicting a process for forming a package substrate 500 is shown, in accordance with an embodiment. The package substrate 500 may be similar to the package substrate 400 shown in FIG. 4B. Though, it is to be appreciated that similar processing operations may be used to form package substrates similar to those shown in FIGS. 4C and 4D.

Referring now to FIG. 5A, a cross-sectional illustration of a package substrate 500 is shown, in accordance with an embodiment. The package substrate 500 may comprise a core 501. The core 501 may comprise glass. In a particular embodiment, the core 501 may include a glass formulation that is suitable for laser assisted etching processes. For example, laser exposure may alter a microstructure or phase of the glass, and render the exposed regions more susceptible to a wet etch than the unexposed regions. In an embodiment, the core 501 may have a thickness between approximately 50 μm and approximately 1,000 μm. Though, thinner or thicker cores 501 may also be used in some embodiments.

Referring now to FIG. 5B, a cross-sectional illustration of the package substrate 500 after via openings 511 are formed is shown, in accordance with an embodiment. In an embodiment, the via openings 511 may be formed with a laser assisted patterning operation. In the illustrated embodiment, sidewalls of the via openings 511 are shown as being substantially vertical. However, in other embodiments, the sidewalls of the via openings 511 may be tapered. For example, the via openings 511 may have hourglass shaped cross-sections. In an embodiment, a seed layer 514 is provided over the core 501. The seed layer 514 may comprise titanium and/or copper in some embodiments. The seed layer 514 may be applied with a sputtering process or the like. In an embodiment, the seed layer 514 is provided over a top surface of the core 501, a bottom surface of the core 501, and along the sidewalls of the via openings 511.

Referring now to FIG. 5C, a cross-sectional illustration of the package substrate after a resist layer 531 is disposed and patterned is shown, in accordance with an embodiment. In an embodiment, the resist layer 531 may be a dry film resist (DFR). The dry film resist may be deposited with a lamination process. The resist layer 531 may then be patterned in order to form openings that are aligned with the via openings 511. In some embodiments, the centerlines of the openings through the resist layer 531 may be slightly offset from a centerline of the via openings 511. This is due to the openings being patterned in different processing operations.

Referring now to FIG. 5D, a cross-sectional illustration of the package substrate 500 after a plating process is shown, in accordance with an embodiment. The plating process may use the exposed portions of the seed layer 514 in order to grow the TGVs 510 and the vias 522. The resist layer 531 blocks growth of the conductive layer between the vias 522. In an embodiment, the TGVs 510 and the vias 522 may comprise copper or the like. Additionally, it is to be appreciated that the vias 522 are formed without the need for an etching process. As such, necking at the interface between the vias 522 and the TGVs 510 is avoided.

Referring now to FIG. 5E, a cross-sectional illustration of the package substrate 500 after the resist layer 531 is removed is shown, in accordance with an embodiment. In an embodiment, the resist layer 531 may be removed with a resist stripping process, a dry etching process, or the like. Removal of the resist layer 531 exposes the sidewalls of the vias 522. Additionally, the seed layer 514 remains and electrically couples the TGVs 510 and vias 522 together.

Referring now to FIG. 5F, a cross-sectional illustration of the package substrate 500 after the exposed portions of the seed layer 514 are removed is shown, in accordance with an embodiment. The seed layer 514 may be removed with a flash etching process or the like. As such, only a small portion of the vias 522 is etched during the removal of the seed layer 514. Removal of the seed layer 514 results in electrical isolation of the TGVs 510 and the vias 522.

Referring now to FIG. 5G, a cross-sectional illustration of the package substrate 500 after a buffer layer 520 is applied over and under the core is shown, in accordance with an embodiment. In an embodiment, the buffer layers 520 may be applied with a lamination process, a CVD process, or the like. In an embodiment, the buffer layers 520 are applied to a thickness that is greater than a thickness of the vias 522. The buffer layers 520 may comprise silicon and nitrogen (e.g., silicon nitride), or titanium and nitrogen (e.g., titanium nitride). The buffer layers 520 may be used as an adhesion promoting layer as well as a mechanical buffer material. In some embodiments, a distinct adhesion promoting layer (not shown) may be provided over the core 501 and the vias 522 before the buffer layers 520 are applied. Such an embodiment would ultimately be similar to the embodiment shown in FIG. 4C.

Referring now to FIG. 5H, a cross-sectional illustration of the package substrate 500 after the vias 522 are exposed is shown, in accordance with an embodiment. In an embodiment, the vias 522 may be exposed using a planarization process (e.g., CMP) or the like. Depending on the processing conditions of the CMP, the top surface of the vias 522 on top of the core 501 may be substantially coplanar with a top surface of the buffer layer 520, and the bottom surface of the vias 522 on the bottom of the core 501 may be substantially coplanar with a bottom surface of the buffer layer 520. In other embodiments, the vias 522 may protrude up above (or below) the buffer layers 520.

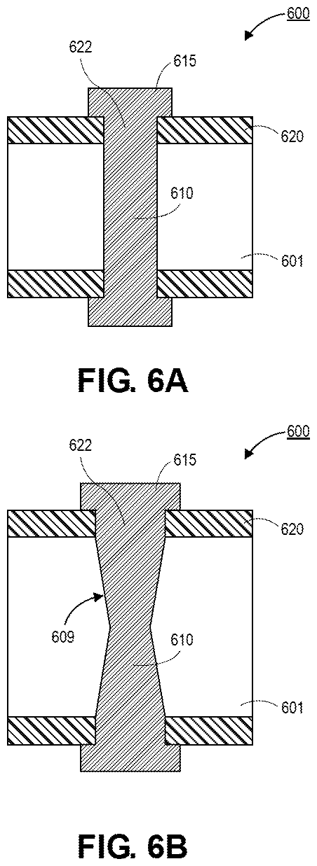

Referring now to FIG. 6A, a cross-sectional illustration of a package substrate 600 is shown, in accordance with an additional embodiment. In an embodiment, the package substrate 600 comprises a core 601, such as a core 601 that comprises glass. In an embodiment, the core 601 may comprise a glass formulation that is suitable for laser assisted patterning. The core 601 may have a thickness between approximately 50 μm and approximately 1,000 μm. In an embodiment, a TGV 610 passes through a thickness of the core 601. The TGV 610 may have substantially vertical sidewalls in some embodiments. Though, in other embodiments, the sidewalls may be tapered, as will be described in greater detail below.

In an embodiment, buffer layers 620 may be provided above and below the core 601. The buffer layers 620 may comprise silicon and nitrogen (e.g., silicon nitride), or titanium and nitrogen (e.g., titanium nitride). In an embodiment, vias 622 may pass through a thickness of the buffer layers 620. The vias 622 may have a width that is substantially equal to a maximum width of the TGV 610. Additionally, a centerline of the vias 622 may be aligned with a centerline of the TGV 610. The aligned orientation of the vias 622 and the TGV 610 may be the result of a single patterning operation used to form the openings for both the TGV 610 and the vias 622. In an embodiment, pads 615 may be provided over and under the vias 622. The pads 615 may have a width that is greater than a width of the vias 622.

Referring now to FIG. 6B, a cross-sectional illustration of a package substrate 600 is shown, in accordance with an additional embodiment. The package substrate 600 in FIG. 6B may be substantially similar to the package substrate 600 in FIG. 6A, with the exception of the TGV 610. Instead of having substantially vertical sidewalls, the TGV 610 has sidewalls 609 that are tapered. In some embodiments, the tapered sidewalls 609 may result in the formation of a TGV 610 that has an hourglass shaped cross-section. Such an embodiment may be the result of dual sided patterning of the core 601. In an embodiment, the maximum width of the TGV 610 (i.e., at the top of the TGV 610 and the bottom of the TGV 610) may be substantially equal to a width of the vias 622. Particularly, an edge of the TGV 610 may be aligned with edges of the vias 622. That is, there may not be a step provided at the interface between the TGV 610 and the vias 622.

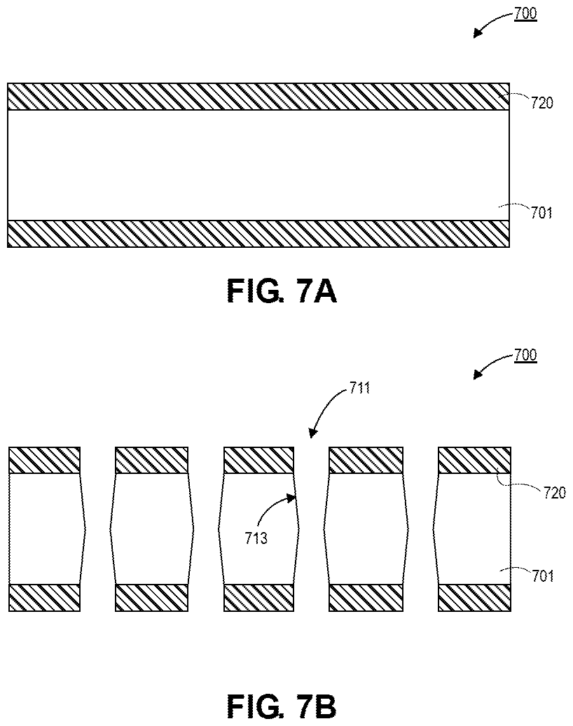

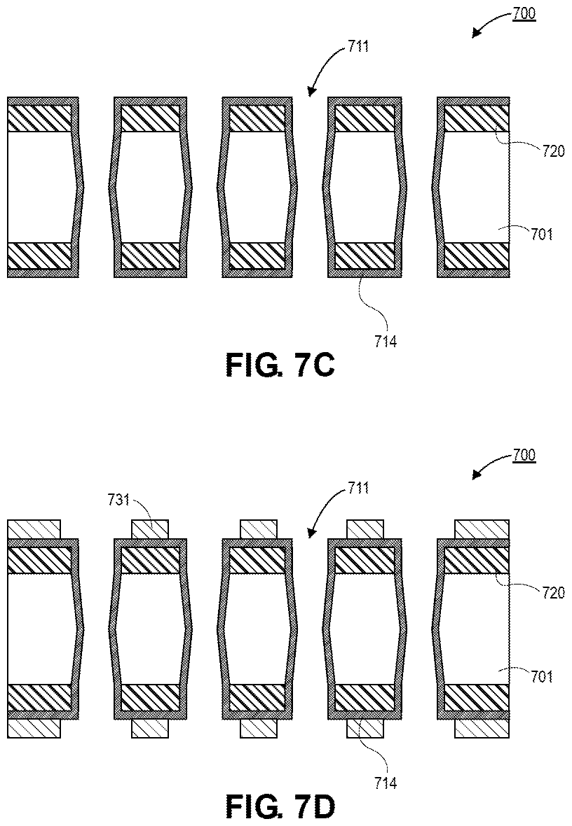

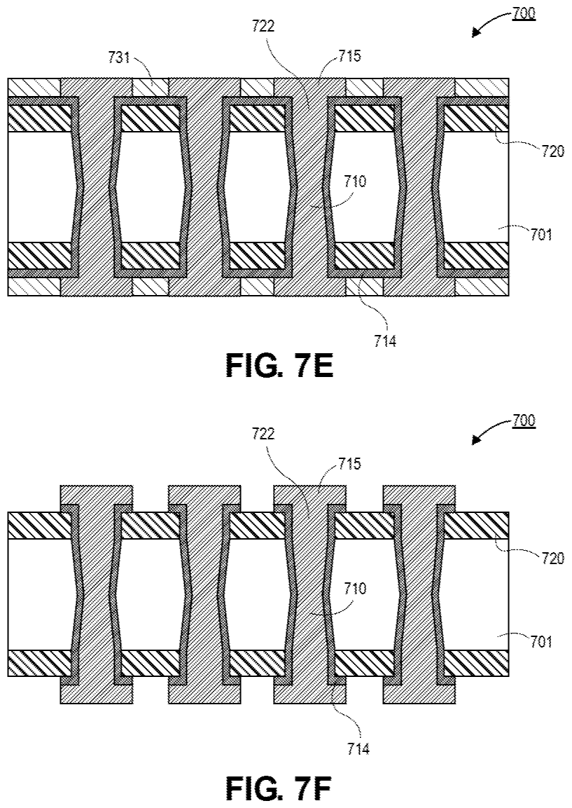

Referring now to FIGS. 7A-7F, a series of cross-sectional illustrations depicting a process for forming a package substrate 700 is shown, in accordance with an embodiment. In an embodiment, the package substrate 700 may be substantially similar to the package substrate 600 in FIG. 6B. Though, it is to be appreciated that other similar package substrate architectures may be formed with similar processing operations.

Referring now to FIG. 7A, a cross-sectional illustration of a package substrate 700 is shown, in accordance with an embodiment. In an embodiment, the package substrate 700 comprises a core 701. The core 701 may comprise glass. In an embodiment, the glass formulation of the core 701 may be suitable for laser assisted patterning. In an embodiment, the core 701 may have any suitable thickness. For example, the core 701 may have a thickness between approximately 50 μm and approximately 1,000 μm.

In an embodiment, buffer layers 720 may be provided above and below the core 701. The buffer layers 720 may be materials suitable for improving adhesion and/or for improving mechanical robustness of the package substrate 700. The buffer layers 720 may comprise silicon and nitrogen (e.g., silicon nitride), or titanium and nitrogen (e.g., titanium nitride). The buffer layers 720 may be applied over the core 701 using lamination, CVD, or any other suitable process.

Referring now to FIG. 7B, a cross-sectional illustration of the package substrate 700 after via openings 711 are formed is shown, in accordance with an embodiment. In an embodiment, via openings 711 may be formed with a laser assisted patterning process. Additionally, the laser process may result in ablation of the buffer layers 720. Since a single laser process is used to form the via openings 711 and the openings through the buffer layers 720, the openings through the buffer layers 720 are self-aligned with the via openings 711. That is, a centerline of the openings through the buffer layers 720 may be substantially aligned with the centerline of the via openings 711.

In an embodiment, the laser assisted patterning process may result in via openings 711 that include tapered sidewalls 713. In a particular embodiment where dual sided patterning is used, the sidewalls 713 may have an hourglass shaped cross-section. Though it is to be appreciated that other etching processes may result in sidewalls 713 that are substantially vertical, similar to the embodiment shown in FIG. 6A.

Referring now to FIG. 7C, a cross-sectional illustration of the package substrate 700 after a seed layer 714 is applied is shown, in accordance with an embodiment. In an embodiment, the seed layer 714 may comprise titanium and/or copper. The seed layer 714 may be applied over the buffer layers 720 and along the sidewalls 713 of the via openings 711. The seed layer 714 may be applied with any suitable deposition process, such as a sputtering process or the like.

Referring now to FIG. 7D, a cross-sectional illustration of the package substrate 700 after a resist layer 731 is disposed and patterned is shown, in accordance with an embodiment. The resist layer 731 may be a DFR or the like. The resist layer 731 may be laminated over the package substrate 700, and patterned with a lithography process. In an embodiment, the resist layer 731 may define regions for the pads of the package substrate 700. That is, openings through the resist layer 731 may be provided over the openings in the buffer layers 720.

Referring now to FIG. 7E, a cross-sectional illustration of the package substrate 700 after a plating process is shown, in accordance with an embodiment. The plating process may use the exposed portions of the seed layer 714 in order to plate up the features of the package substrate 700, such as the TGVs 710, the vias 722 through the buffer layer 720, and the pads 715. As shown, the TGVs 710 may have hourglass shaped cross-sections, and the vias 722 through the buffer layer 720 may have rectangular shaped cross-sections. In an embodiment, the vias 722 may be substantially aligned with the TGVs 710.

Referring now to FIG. 7F, a cross-sectional illustration of the package substrate 700 after the resist layer 731 is removed is shown, in accordance with an embodiment. The resist layer 731 may be removed with a stripping process, a dry etching process, or the like. In an embodiment, portions of the seed layer 714 that were below the resist layer 731 may also be etched. For example, a flash etching process may be used in order to remove exposed portions of the seed layer 714. Removal of the seed layer 714 results in the TGVs 710 being electrically isolated from each other.

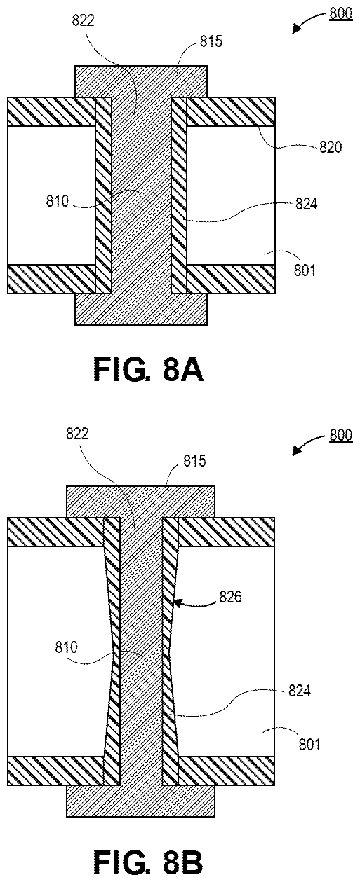

Referring now to FIG. 8A, a cross-sectional illustration of a package substrate 800 is shown, in accordance with an embodiment. In an embodiment, the package substrate 800 comprises a core 801. The core 801 may comprise glass. In an embodiment, the core 801 may comprise a glass formulation suitable for laser assisted etching operations. In an embodiment, a TGV 810 passes through a thickness of the core 801. Vias 822 pass through the buffer layers 820. In an embodiment, the vias 822 have a width that is substantially equal to a width of the TGV 810. Additionally, the TGV 810 may be substantially aligned with the vias 822. This is due to the vias 822 and the TGV 810 being patterned with a single patterning operation. In an embodiment, pads 815 may be provided over and under the core 701. The pads 815 may be coupled to the TGV 810 by the vias 822.

In an embodiment, the TGV 810 may be separated from the core 801 by a liner 824. The liner 824 may comprise the same material as the buffer layers 820. While shown as having a seam between the liner 824 and the buffer layers 820, it is to be appreciated that the liner 824 and the buffer layers 820 may be a single interface free material. The liner 824 may also be provided along sidewalls of the vias 822.

Referring now to FIG. 8B, a cross-sectional illustration of a package substrate 800 is shown, in accordance with an additional embodiment. The package substrate 800 in FIG. 8B may be substantially similar to the package substrate 800 in FIG. 8A, with the exception of the architecture of the liner 824. Instead of having only vertical sidewalls, the liner 824 may have tapered sidewalls 826. The tapered sidewalls 826 may interface with the core 801. The opposite side of the liner 824 may have vertical sidewalls. That is, the interface between the TGV 810 and the liner 824 may be a vertical interface.

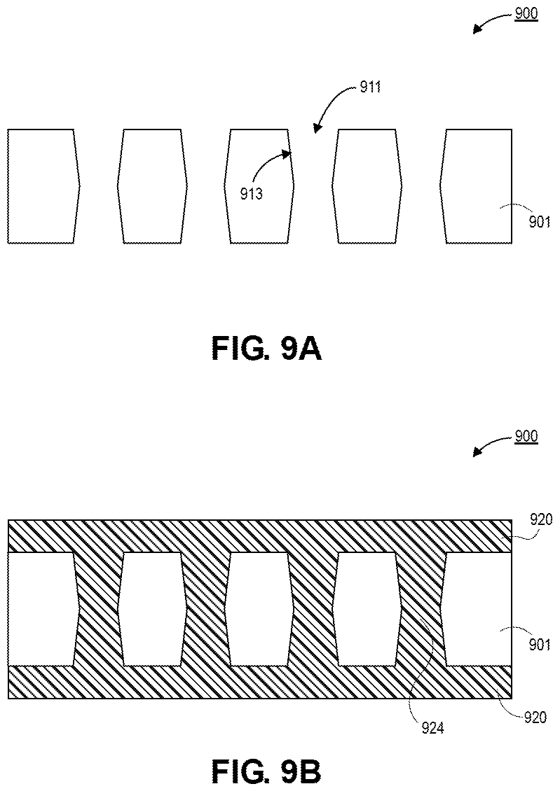

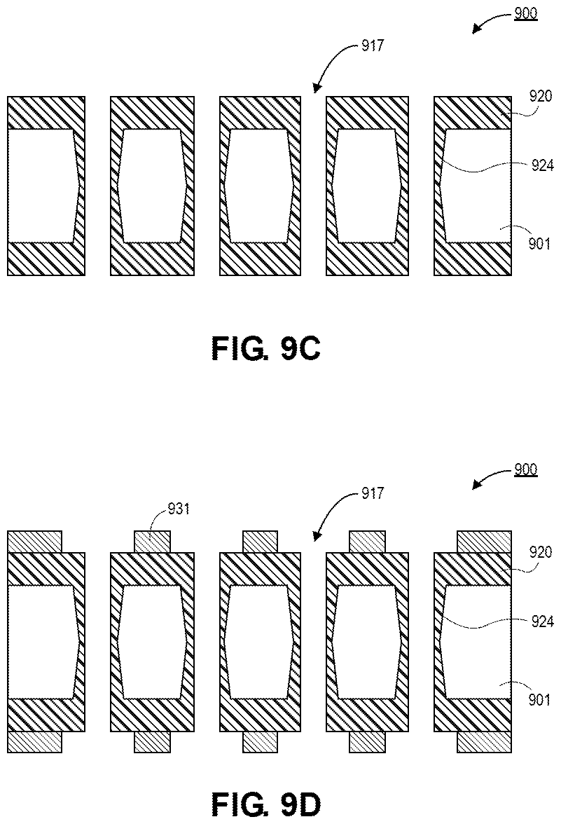

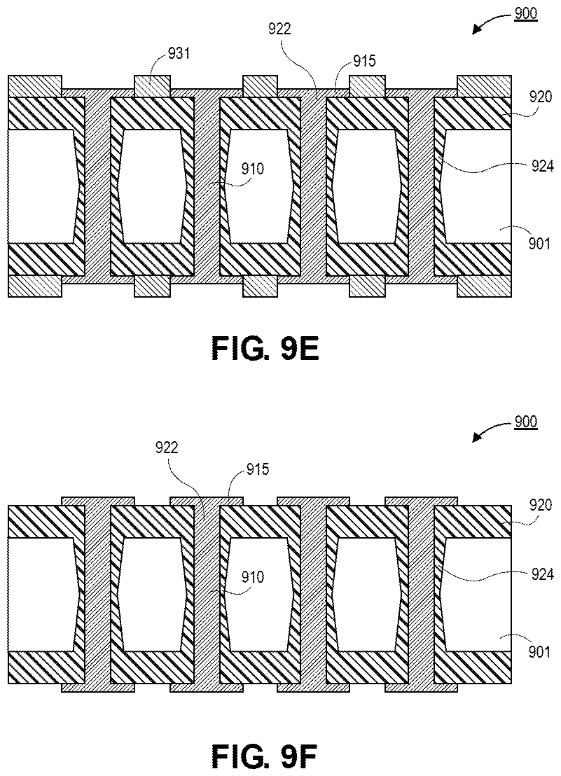

Referring now to FIGS. 9A-9F, a series of cross-sectional illustrations depicting a process for forming a package substrate 900 is shown, in accordance with an embodiment. In an embodiment, the package substrate 900 is similar to the package substrate 800 in FIG. 8B. Though, it is to be appreciated that similar embodiments may be used in order to fabricate a package substrate similar to the package substrate 800 in FIG. 8A.

Referring now to FIG. 9A, a cross-sectional illustration of a package substrate 900 is shown, in accordance with an embodiment. In an embodiment, the package substrate 900 may include core 901. The core 901 may comprise glass in some embodiments. In an embodiment, the core 901 may be suitable for laser assisted patterning operations. For example, via openings 911 are provided through the core 901. The via openings 911 may include a tapered sidewalls 913 in some embodiment. The via openings 911 may have an hourglass shaped cross-section.

Referring now to FIG. 9B, a cross-sectional illustration of the package substrate 900 after a buffer layer 920 is applied is shown, in accordance with an embodiment. In an embodiment, the buffer layer 920 may be provided over top and bottom surfaces of the core 901. Additionally, a liner 924 of the buffer layer 920 may be provided in the via openings 911. The buffer layer 920 may comprise silicon and nitrogen (e.g., silicon nitride), or titanium and nitrogen (e.g., titanium nitride). In other embodiments, the buffer layer 920 may comprise a PID. The buffer layer 920 may be applied with a lamination process, a CVD process, or the like.

Referring now to FIG. 9C, a cross-sectional illustration of the package substrate after openings 917 are formed through the buffer layer 920 and the liner 924. In an embodiment, the openings 917 may be formed with a lithography patterning process. In the case of a PID buffer layer 920, the buffer layer 920 may be directly exposed and patterned. In the case of other materials, a photoresist layer may be provided over the buffer layer 920, the photoresist layer may be patterned, and the pattern may be transferred into the buffer layer 920 with an etching process. In an embodiment, the openings 917 may have substantially vertical sidewalls. As such, the liner 924 will have tapered sidewalls along an outer perimeter and vertical sidewalls along an inner perimeter. In an embodiment, a seed layer (not shown) may be provided over the buffer layer 920 and the inner sidewalls of the liner 924.

Referring now to FIG. 9D, a cross-sectional illustration of the package substrate 900 after a resist layer 931 is disposed over the package substrate 900 is shown, in accordance with an embodiment. The resist layer 931 may be a DFR in some embodiments. Openings through the resist layer 931 may be provided over the openings 917 in the buffer layer 920.

Referring now to FIG. 9E, a cross-sectional illustration of the package substrate 900 after a plating process is shown, in accordance with an embodiment. In an embodiment, the plating process may result in the formation of TGVs 910, vias 922 through the buffer layers 920, and pads 915 over the buffer layers 920. In an embodiment, the vias 922 and the TGVs 910 may be substantially aligned with each other. For example, a centerline of the TGVs 910 may be substantially aligned with a centerline of the vias 922. Additionally, a width of the TGVs 910 may be substantially equal to a width of the vias 922.

Referring now to FIG. 9F, a cross-sectional illustration of the package substrate 900 after the resist layer 931 is removed is shown, in accordance with an embodiment. In an embodiment, the resist layer 931 may be removed with a stripping or etching process. Additionally, at this point the seed layer (not shown) may be etched from between the pads 915. As such the TGVs 910 are now electrically isolated from each other.

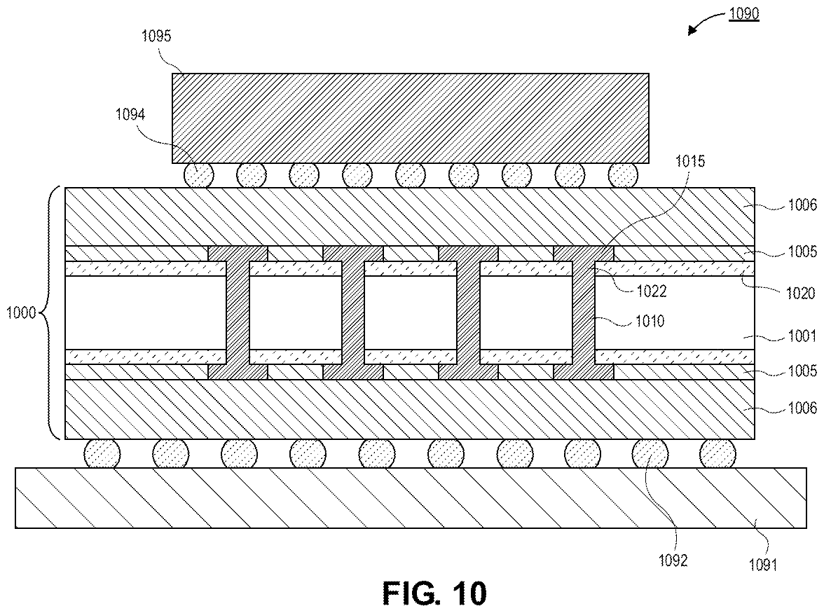

Referring now to FIG. 10, a cross-sectional illustration of an electronic system 1090 is shown, in accordance with an embodiment. In an embodiment, the electronic system 1090 may comprise a board 1091, such as a printed circuit board (PCB). In an embodiment, the board 1091 is coupled to a package substrate 1000 by interconnects 1092. While shown as solder interconnects 1092, it is to be appreciated that any interconnect 1092 architecture may be used to couple the package substrate 1000 to the board 1091.

In an embodiment, the package substrate 1000 may comprise a core 1001. The core 1001 may be a glass core. In some embodiments, the core 1001 may be suitable for laser assisted patterning operations. In an embodiment, TGVs 1010 may be provided through a thickness of the core 1001. The TGVs 1010 may have vertical sidewalls. In other embodiments, the TGVs 1010 may have tapered sidewalls, such as having an hourglass shaped cross-section. In an embodiment, buffer layers 1020 may be provided over the top and bottom surfaces of the core 1001. The buffer layers 1020 may comprise silicon and nitrogen (e.g., silicon nitride), or titanium and nitrogen (e.g., titanium nitride). In an embodiment, vias 1022 may be provided through the buffer layers 1020. The vias 1022 may be aligned with the TGVs 1010. In a particular embodiment, the vias 1022 may have a width that is substantially equal to a maximum width of the TGVs 1010. As such, there is no current choke point to diminish electrical performance. Pads 1015 may be provided over the vias 1022.

In an embodiment, the package substrate 1000 may also comprise buildup layers 1005 over the pads 1015. Additional buildup layers 1006 may be provided above and below the core 1001. Conductive routing (not shown) may be provided in the buildup layers 1006 in order to couple the TGVs 1010 to other features of the electronic system 1090. In the illustrated embodiment, the package substrate 1000 may be substantially similar to the package substrate 200 in FIG. 2. However, it is to be appreciated that any of the package substrates described in herein may be integrated into the electronic system 1090.

In an embodiment, one or more dies 1095 may be coupled to the package substrate 1000. For example, interconnects 1094 may couple the die 1095 to the package substrate 1000. While shown as a solder interconnect 1094, it is to be appreciated that the interconnects 1094 may include any first level interconnect (FLI) architecture.

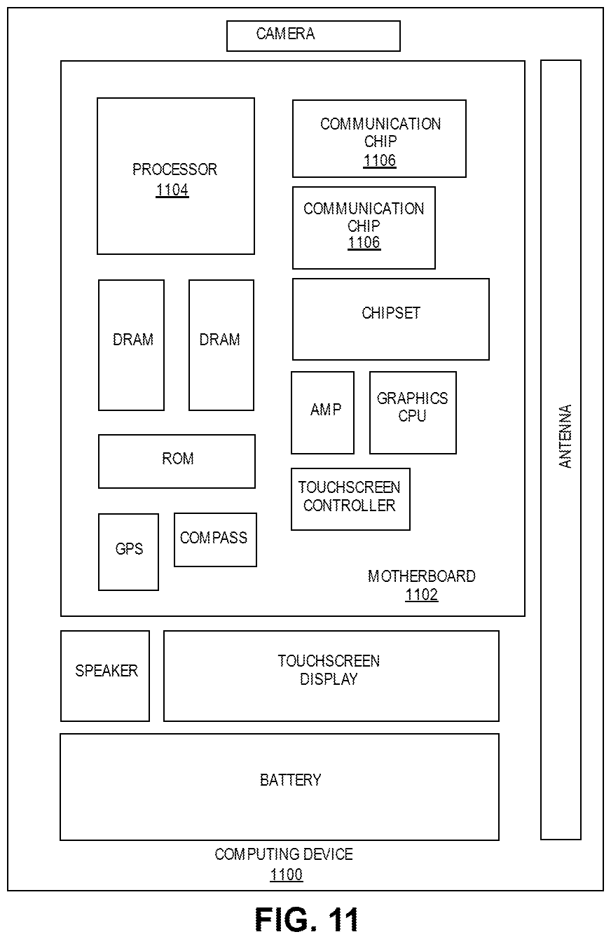

FIG. 11 illustrates a computing device 1100 in accordance with one implementation of the invention. The computing device 1100 houses a board 1102. The board 1102 may include a number of components, including but not limited to a processor 1104 and at least one communication chip 1106. The processor 1104 is physically and electrically coupled to the board 1102. In some implementations the at least one communication chip 1106 is also physically and electrically coupled to the board 1102. In further implementations, the communication chip 1106 is part of the processor 1104.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1106 enables wireless communications for the transfer of data to and from the computing device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1106 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1100 may include a plurality of communication chips 1106. For instance, a first communication chip 1106 may be dedicated to shorter range wireless communications such as Wi-Fi and Bluetooth and a second communication chip 1106 may be dedicated to longer range wireless communications such as GPS, EDGE, GPRS, CDMA, WiMAX, LTE, Ev-DO, and others.

The processor 1104 of the computing device 1100 includes an integrated circuit die packaged within the processor 1004. In some implementations of the invention, the integrated circuit die of the processor may be part of an electronic system that includes a glass core with buffer layers and vias through the glass core, in accordance with embodiments described herein. The term “processor” may refer to any device or portion of a device that processes electronic data from registers and/or memory to transform that electronic data into other electronic data that may be stored in registers and/or memory.

The communication chip 1106 also includes an integrated circuit die packaged within the communication chip 1106. In accordance with another implementation of the invention, the integrated circuit die of the communication chip may be part of an electronic system that includes a glass core with buffer layers and vias through the glass core, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package substrate, comprising: a core, wherein the core comprises glass; a first layer under the core; a second layer over the core; a via through the core, the first layer, and the second layer, wherein a width of the via through the core is equal to a width of the via through the first layer and the second layer; a first pad under the via; and a second pad over the via.

Example 2: the package substrate of Example 1, wherein the first layer and the second layer comprise a photoimageable dielectric (PID).

Example 3: the package substrate of Example 1 or Example 2, wherein the first layer and the second layer comprise silicon and nitrogen.

Example 4: the package substrate of Example 1 or Example 2, wherein the first layer and the second layer comprise titanium and nitrogen.

Example 5: the package substrate of Examples 1-4, wherein the via comprises an hourglass shaped cross-section through the core.

Example 6: the package substrate of Example 5, wherein the via comprises rectangular cross-sections through the first layer and the second layer.

Example 7: the package substrate of Examples 1-6, further comprising: a first buildup layer under the first layer; and a second buildup layer over the second layer.

Example 8: the package substrate of Example 7, wherein the first pad is in the first buildup layer, and wherein the second pad is in the second buildup layer.

Example 9: the package substrate of Examples 1-8, wherein a width of the first pad and the second pad is greater than a width of the via through the first layer and the second layer.

Example 10: the package substrate of Examples 1-9, wherein a centerline of a portion of the via through the core is aligned with a centerline of the via through the first layer and the second layer.

Example 11: a method of forming a package substrate, comprising: providing a core, wherein the core comprises glass; forming a first layer under the core and a second layer over the core; forming openings in the first layer and the second layer; forming a via opening through the core, wherein the via opening is aligned with the openings in the first layer and the second layer; plating a via in the via opening and the openings in the first layer and the second layer; and forming pads under and over the via.

Example 12: the method of Example 11, wherein the first layer and the second layer are patterned with an etch through a mask layer.

Example 13: the method of Example 11 or Example 12, wherein the first layer and the second layer are photoimageable dielectrics (PIDs), and wherein forming the openings in the first layer and the second layer includes an exposure and develop process.

Example 14: the method of Examples 11-13, wherein the via openings are formed with a laser assisted patterning process.

Example 15: the method of Example 14, wherein the via openings have an hourglass shaped cross-section.

Example 16: the method of Examples 11-15, wherein a maximum width of the via opening is equal to a width of the openings in the first layer and the second layer.

Example 17: the method of Example 16, wherein centerlines of the openings in the first layer and the second layer are aligned with a centerline of the via opening.

Example 18: the method of Examples 11-17, further comprising: forming buildup layers under and over the first layer and the second layer.

Example 19: the method of Examples 11-18, wherein a cross-sectional shape of the openings through the first layer and the second layer is rectangular.

Example 20: the method of Examples 11-19, wherein the via and the pads are formed with a single plating process.

Example 21: an electronic system, comprising: a board; a package substrate coupled to the board, wherein the package substrate comprises: a core, wherein the core comprises glass; a first buffer layer under the core and a second buffer layer over the core; a via through the core, the first buffer layer, and the second buffer layer, wherein the via comprises an hourglass shaped cross-section through the core and rectangular shaped cross-sections through the first buffer layer and the second buffer layer; and pads under and over the via; and a die coupled to the package substrate.

Example 22: the electronic system of Example 21, wherein first buffer layer and the second buffer layer comprise silicon and nitrogen, or titanium and nitrogen.

Example 23: the electronic system of Example 21 or Example 22, wherein the first buffer layer and the second buffer layer comprise a photoimageable dielectric (PID).

Example 24: the electronic system of Examples 21-23, wherein a width of the via through the first buffer layer and the second buffer layer is equal to a maximum width of the via through the core.

Example 25: the electronic system of Examples 21-24, wherein the pads have a width that is greater than a maximum width of the via.

Example 26: a package substrate, comprising: a core, wherein the core comprises glass; a first buffer layer under the core; a second buffer layer over the core; a via through the core; a first pad in the first buffer layer and coupled to the via; and a second pad in the second buffer layer and coupled to the via.

Example 27: the package substrate of Example 26, further comprising: a layer between the core and the first buffer layer and between the core and the second buffer layer.

Example 28: the package substrate of Example 27, wherein the layer extends up sidewalls of the first pad and the second pad.

Example 29: the package substrate of Examples 26-28, wherein the via has substantially vertical sidewalls.

Example 30: the package substrate of Examples 26-29, wherein the via has tapered sidewalls.

Example 31: the package substrate of Example 30, wherein the via has an hourglass shaped cross-section.

Example 32: the package substrate of Examples 26-31, wherein a top surface of the second pad is substantially coplanar with a top surface of the second buffer layer, and wherein a bottom surface of the first pad is substantially coplanar with a bottom surface of first buffer layer.

Example 33: the package substrate of Examples 26-32, wherein a seed layer is provided between the via and the core.

Example 34: the package substrate of Examples 26-32, wherein the first buffer layer and the second buffer layer comprise a dielectric material.

Example 35: the package substrate of Example 34, wherein the first buffer layer and the second buffer layer comprise silicon and nitrogen, or titanium and nitrogen.

Example 36: a method of forming a package substrate, comprising: forming a via opening through a core, wherein the core comprises glass; applying resist layers over a top surface of the core and a bottom surface of the core, wherein openings are patterned into the resist layers over and under the via opening; plating a via in the via opening and pads in the openings patterned into the resist layers; removing the resist layers; disposing buffer layers over and under the pads; and recessing the buffer layers to expose the pads.

Example 37: the method of Example 36, further comprising: forming a seed layer over the core before applying the resist layers; and etching exposed portions of the seed layer after the resist layers are removed.

Example 38: the method of Example 36 or Example 37, wherein the buffer layers are recessed with a chemical mechanical planarizing (CMP) process.

Example 39: the method of Example 38, wherein top and bottom surfaces of the pads are coplanar with top and bottom surfaces of the buffer layers.

Example 40: the method of Examples 36-39, wherein the via opening has an hourglass shaped cross-section.

Example 41: the method of Examples 36-40, wherein the buffer layers directly contact the core.

Example 42: the method of Examples 36-41, wherein an adhesion promoting layer is provided between the buffer layers and the core.

Example 43: the method of Examples 36-42, wherein the buffer layers comprise silicon and nitrogen, or titanium and nitrogen.

Example 44: the method of Examples 36-43, wherein the pads have a width that is greater than a maximum width of the via.

Example 45: the method of Examples 36-44, wherein the resist layers are dry film resist (DFR) layers.

Example 46: an electronic system, comprising: a board; a package substrate coupled to the board, wherein the package substrate comprises: a core, wherein the core comprises glass; a first buffer layer under the core; a second buffer layer over the core; a via through the core, wherein the via comprises an hourglass shaped cross-section; a first pad in the first buffer layer and coupled to the via, wherein a bottom surface of the first pad is substantially coplanar with a bottom surface of the first buffer layer; and a second pad in the second buffer layer and coupled to the via, wherein a top surface of the second pad is substantially coplanar with a top surface of the second buffer layer; and a die coupled to the package substrate.

Example 47: the electronic system of Example 46, wherein the first buffer layer and the second buffer layer are directly contacting the core.

Example 48: the electronic system of Example 46 or Example 47, wherein the first buffer layer and the second buffer layer are spaced apart from the core by an adhesion promoting layer.

Example 49: the electronic system of Examples 46-48, wherein a width of the first pad and the second pad is greater than a maximum width of the via.

Example 50: the electronic system of Examples 46-49, further comprising: a seed layer between the via and the core.

Example 51: a package substrate, comprising: a core, wherein the core comprises glass; a first buffer layer under the core; a second buffer layer over the core; a via through the core, the first buffer layer, and the second buffer layer; and pads over and under the via.

Example 52: the package substrate of Example 51, wherein the via has an hourglass shaped cross-section through the core.

Example 53: the package substrate of Example 51 or Example 52, wherein the via has rectangular shaped cross-sections in the first buffer layer and the second buffer layer.

Example 54: the package substrate of Example 53, wherein a maximum width of the via through the core is equal to a maximum width of the via through the first buffer layer and the second buffer layer.

Example 55: the package substrate of Example 54, wherein a centerline of the via through the first buffer layer is aligned with a centerline of the via through the core.

Example 56: the package substrate of Example 55, wherein an edge of the via through the first buffer layer is aligned with an edge of the via through the core.

Example 57: the package substrate of Examples 51-56, wherein the pads have a width that is greater than a maximum width of the via.

Example 58: the package substrate of Examples 51-56, wherein the first buffer layer and the second buffer layer comprise an adhesion promoting material.

Example 59: the package substrate of Example 58, wherein the first buffer layer and the second buffer layer comprise silicon and nitrogen, or titanium and nitrogen.

Example 60: the package substrate of Examples 51-59, wherein a seed layer is provided between the via and the core.

Example 61: a method of forming a package substrate, comprising: forming buffer layers over and under a core, wherein the core comprises glass; forming a via opening through the buffer layers and the core; applying a resist layer over the buffer layers, and patterning the resist layer to form pad openings above the buffer layers; plating the via in the via opening and plating the pads in the pad openings; and removing the resist layer.

Example 62: the method of Example 61, wherein the via opening through the buffer layers and the core is at least partially formed with a laser exposure.

Example 63: the method of Example 62, wherein the laser exposure ablates the buffer layer and induces a microstructure or phase change in the core, and wherein the core is etched after the exposure.

Example 64: the method of Example 62 or Example 63, wherein the via through the core is aligned with the via through the buffer layers.

Example 65: the method of Examples 61-64, further comprising: disposing a seed layer over the via opening and the buffer layers.

Example 66: the method of Example 65, further comprising: removing exposed portions of the seed layer after removing the resist layer.

Example 67: the method of Example 65 or Example 66, wherein the via opening has an hourglass shaped cross-section through the core.

Example 68: the method of Example 67, wherein the via opening has a rectangular shaped cross-section through the buffer layers.

Example 69: the method of Example 67 or Example 68, wherein a width of the via opening through the buffer layers is equal to a maximum width of the via opening through the core.

Example 70: the method of Examples 61-69, wherein buffer layers comprise silicon and nitrogen, or titanium and nitrogen.

Example 71: an electronic system, comprising: a board; a package substrate coupled to the board, wherein the package substrate comprises: a core, wherein the core comprises glass; buffer layers over and under the core; a via through the core and the buffer layers, wherein the via has an hourglass shaped cross-section through the core and a rectangular shaped cross-section through the buffer layers; and pads over and under the via; and a die coupled to the package substrate.

Example 72: the electronic system of Example 71, wherein a centerline of the via through the buffer layers is aligned with a centerline of the via through the core.

Example 73: the electronic system of Example 71 or Example 72, wherein the pads are wider than the via.

Example 74: the electronic system of Examples 71-73, wherein the buffer layers comprise silicon and nitrogen, or titanium and nitrogen.

Example 75: the electronic system of Examples 71-74, wherein a seed layer is provided between the via and the core.

Example 76: a package substrate, comprising: a core, wherein the core comprises glass; buffer layers over and under the core; a via through the core and the buffer layers, wherein a liner is provided between the via and the core; and pads over the via.

Example 77: the package substrate of Example 76, wherein the liner is the same material as the buffer layers.

Example 78: the package substrate of Example 76 or Example 77, wherein the via has vertical sidewalls.

Example 79: the package substrate of Example 78, wherein the liner has tapered sidewalls.

Example 80: the package substrate of Example 79, wherein the liner further includes vertical sidewalls.

Example 81: the package substrate of Examples 76-80, wherein the buffer layer comprises silicon and nitrogen, or titanium and nitrogen.

Example 82: the package substrate of Examples 76-81, wherein a width of the via through the buffer layers is equal to a width of the via through the core.

Example 83: the package substrate of Examples 76-82, wherein the pads are wider than the via.

Example 84: the package substrate of Examples 76-83, wherein the buffer layers comprise a photoimageable dielectric (PID).

Example 85: the package substrate of Examples 76-84, further comprising a seed layer between the via and the liner.

Example 86: a method of forming a package substrate, comprising: forming a via opening through a core, wherein the core comprises glass; disposing a buffer material over and under the core, wherein the buffer material fills the via opening; patterning an opening through the buffer material, wherein the opening is within the via opening; disposing a resist layer over the buffer material; patterning the resist layer to form pad openings over the opening; plating a via and pads; and removing the resist layer.

Example 87: the method of Example 86, wherein the via opening has an hourglass shaped cross-section.

Example 88: the method of Example 86 or Example 87, wherein the opening through the buffer material has vertical sidewalls.

Example 89: the method of Examples 86-87, wherein the buffer material is a photoimageable dielectric (PID).

Example 90: the method of Examples 86-89, wherein a width of the via through the buildup material above and below the core is equal to a width of the via through the core.

Example 91: the method of Examples 86-90, wherein the resist layer is a dry film resist (DFR).

Example 92: the method of Examples 86-91, wherein the pads and the via are formed with a single plating process.

Example 93: the method of Examples 86-92, further comprising: removing a seed layer after removing the resist layer.

Example 94: the method of Examples 86-92, wherein the buffer material comprises silicon and nitrogen, or titanium and nitrogen.

Example 95: the method of Examples 86-92, wherein the pads have a width greater than a width of the via.

Example 96: an electronic system, comprising: a board; a package substrate coupled to the board, wherein the package substrate comprises: a core, wherein the core comprises glass; a via through the core; a liner between the via and the core, wherein the liner comprises a photoimageable dielectric (PID); and pads over and under the via; and a die coupled to the package substrate.

Example 97: the electronic system of Example 96, wherein the via has vertical sidewalls.

Example 98: the electronic package of Example 97, wherein the liner has tapered sidewalls in contact with the core.

Example 99: the electronic package of Examples 96-98, wherein a buffer layer is provided above and below the core, wherein the pads are on the buffer layer.

Example 100: the electronic package of Example 99, wherein the buffer layer is the same material as the liner.

What is claimed is:

1. A package substrate, comprising:
a core, wherein the core comprises glass;
a first layer under the core;
a second layer over the core;
a via through the core, the first layer, and the second layer, wherein a width of the via through the core is equal to a width of the via through the first layer and the second layer;
a first pad under the via; and
a second pad over the via.

2. The package substrate of claim 1, wherein the first layer and the second layer comprise a photoimageable dielectric (PID).

3. The package substrate of claim 1, wherein the first layer and the second layer comprise silicon and nitrogen.

4. The package substrate of claim 1, wherein the first layer and the second layer comprise titanium and nitrogen.

5. The package substrate of claim 1, wherein the via comprises an hourglass shaped cross-section through the core.

6. The package substrate of claim 5, wherein the via comprises rectangular cross-sections through the first layer and the second layer.

7. The package substrate of claim 1, further comprising:
a first buildup layer under the first layer; and
a second buildup layer over the second layer.

8. The package substrate of claim 7, wherein the first pad is in the first buildup layer, and wherein the second pad is in the second buildup layer.

9. The package substrate of claim 1, wherein a width of the first pad and the second pad is greater than a width of the via through the first layer and the second layer.

10. The package substrate of claim 1, wherein a centerline of a portion of the via through the core is aligned with a centerline of the via through the first layer and the second layer.

11. A method of forming a package substrate, comprising:
providing a core, wherein the core comprises glass;
forming a first layer under the core and a second layer over the core;
forming openings in the first layer and the second layer;
forming a via opening through the core, wherein the via opening is aligned with the openings in the first layer and the second layer;
plating a via in the via opening and the openings in the first layer and the second layer; and
forming pads under and over the via.

12. The method of claim 11, wherein the first layer and the second layer are patterned with an etch through a mask layer.

13. The method of claim 11, wherein the first layer and the second layer are photoimageable dielectrics (PIDs), and wherein forming the openings in the first layer and the second layer includes an exposure and develop process.

14. The method of claim 11, wherein the via openings are formed with a laser assisted patterning process.

15. The method of claim 14, wherein the via openings have an hourglass shaped cross-section.

16. The method of claim 11, wherein a maximum width of the via opening is equal to a width of the openings in the first layer and the second layer.

17. The method of claim 16, wherein centerlines of the openings in the first layer and the second layer are aligned with a centerline of the via opening.

18. The method of claim 11, further comprising:
forming buildup layers under and over the first layer and the second layer.

19. The method of claim 11, wherein a cross-sectional shape of the openings through the first layer and the second layer is rectangular.

20. The method of claim 11, wherein the via and the pads are formed with a single plating process.

21. An electronic system, comprising:
a board;
a package substrate coupled to the board, wherein the package substrate comprises:
a core, wherein the core comprises glass;
a first buffer layer under the core and a second buffer layer over the core;
a via through the core, the first buffer layer, and the second buffer layer, wherein the via comprises an hourglass shaped cross-section through the core and rectangular shaped cross-sections through the first buffer layer and the second buffer layer; and
pads under and over the via; and
a die coupled to the package substrate.

22. The electronic system of claim 21, wherein first buffer layer and the second buffer layer comprise silicon and nitrogen, or titanium and nitrogen.

23. The electronic system of claim 21, wherein the first buffer layer and the second buffer layer comprise a photoimageable dielectric (PID).

24. The electronic system of claim 21, wherein a width of the via through the first buffer layer and the second buffer layer is equal to a maximum width of the via through the core.

25. The electronic system of claim 21, wherein the pads have a width that is greater than a maximum width of the via.
